(19) United States
(12) Patent Application Publication
(10) Pub. No.: US 2026/0244342 A1
(43) Pub. Date: Aug. 20, 2026

(54) READ DISTURB SCAN WITH DYNAMIC WL LIST

(71) Applicant: Micron Technology, Inc., Boise, ID (US)

(72) Inventors: Lei Lin, Fremont, CA (US); Guang Hu, Mountain View, CA (US); Jianmin Huang, San Carlos, CA (US)

(21) Appl. No.: 19/056,404

(22) Filed: Feb. 18, 2025

(51) Int. Cl. G06F 3/06; G11C 16/34

(52) U.S. Cl. CPC G06F 3/061; G06F 3/0653; G06F 3/0659; G06F 3/0679; G11C 16/3427

(57) ABSTRACT

This disclosure is directed to a system for performing read disturb handling. The system tracks read stress counts for a plurality of word lines (WLs) in a portion of the memory device. The system, in response to determining that a read count (RC) threshold for the portion of the memory device has been reached, selectively adds one or more WLs from the plurality of WLs to a WL list comprising a set of predefined mandatory WLs based on the read stress counts of the one or more WLs. The system performs a read disturb handling (RDH) operation on WLs in the WL list.

### TECHNICAL FIELD

Examples of the disclosure relate generally to memory sub-systems and, more specifically, to performing read disturb handling (RDH) operations.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various examples of the disclosure. The drawings, however, should not be taken to limit the disclosure to the specific examples, but are for explanation and understanding only.

FIG. 1 is a block diagram illustrating an example computing system that includes a memory sub-system, in accordance with some examples.

FIG. 2 illustrates a diagram of stages for selectively adding word lines (WLs) for RDH operations, in accordance with some examples.

FIG. 3 illustrates a diagram of a table for tracking read stress counts for WL groups, in accordance with some examples.

FIG. 4 illustrates a diagram of different lists of WLs satisfying read stress count criteria for different virtual blocks (VBs), in accordance with some examples.

FIG. 5 illustrates a diagram of operations performed using a RDH component, in accordance with some examples.

FIG. 6 illustrates a diagram of operations performed using a RDH component, in accordance with some examples.

FIG. 7 is a block diagram of an example computer system, according to some examples.

### DETAILED DESCRIPTION

The present disclosure is directed to a system including a memory device and a processing device, operatively coupled to the memory device, configured to perform operations that improve RDH operations, such as read disturb scan operations. The system does this by dynamically tracking and managing WL stress counts during read operations. Specifically, the disclosed processing device maintains read stress counts for WLs in different memory blocks (e.g., VBs), tracking both direct read operations on target WLs being read and stress effects on neighboring WLs. When a read count threshold for the block is reached (triggering RDH operations), the processing device identifies WLs associated with read stress counts that satisfy one or more criteria. The processing device can then dynamically add the identified WLs to a WL list that includes predefined mandatory WLs to be scanned in the RDH operations. Rather than scanning all WLs or maintaining a fixed scan list, the processing device selectively adds only those WLs with stress counts satisfying one or more criteria (e.g., having stress counts that exceed a defined threshold or having stress counts that is greater than stress counts of other WLs by some threshold amount), optimizing the balance between reliability and performance. The processing device then performs the RDH operation on the WL list (including the dynamically added WLs), removing the dynamically added WLs after performing the RDH operation. This approach enhances read disturb detection precision while maintaining efficient operation by avoiding unnecessary scanning of all WLs. This can significantly improve overall system performance and the efficiency of the memory sub-system.

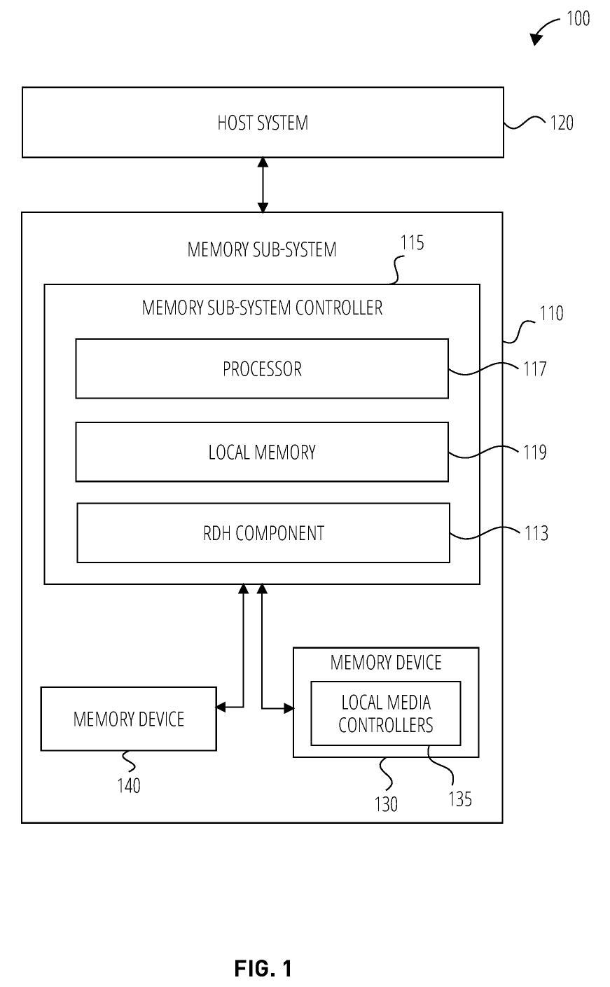

A memory sub-system can be a storage device, a memory module, or a hybrid of a storage device and memory module. Examples of storage devices and memory modules are described below in conjunction with FIG. 1. In general, a host system can utilize a memory sub-system that includes one or more components, such as memory devices that store data. The host system can send access requests to the memory sub-system, such as to store data at the memory sub-system and to read data from the memory sub-system.

The host system can send access requests (e.g., write command, read command, erase command) to the memory sub-system, such as to store data on a memory device at the memory sub-system, read data from the memory device on the memory sub-system, or write/read constructs (e.g., such as submission and completion queues) with respect to a memory device on the memory sub-system. The data to be read or written, as specified by a host request, is hereinafter referred to as “host data” or “user data.”

A host request can include logical address information (e.g., logical block address (LBA), namespace) for the host data, which is the location the host system associates with the host data and a particular zone in which to store or access the host data. The logical address information (e.g., LBA, namespace) can be part of metadata for the host data. Metadata can also include error handling data (e.g., error-correcting code (ECC) code word, parity code), data version (e.g., used to distinguish age of data written), valid bitmap (which LBAs or logical transfer units contain valid data), and so forth.

The memory sub-system can initiate media management operations, such as a write operation, on host data that is stored on a memory device. For example, firmware of the memory sub-system may re-write previously written host data from a location of a memory device to a new location as part of garbage collection (GC) management operations. The data that is re-written, for example as initiated by the firmware, is hereinafter referred to as “GC data.” Examples of system data include, but are not limited to, system tables (e.g., logical-to-physical memory address mapping table, also referred to herein as a logical-to-physical (L2P) mapping table (referred to as an L2P table), data from logging, scratch pad data, and so forth).

A memory device can be a non-volatile memory device. A non-volatile memory device is a package of one or more die. Each die can be comprised of one or more planes. For some types of non-volatile memory devices (e.g., AND-type devices), each plane is comprised of a set of physical blocks. For some memory devices, blocks are the smallest area that can be erased. Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND), which are raw memory devices combined with a local embedded controller for memory management within the same memory device package. The memory device can be divided into one or more zones where each zone is associated with a different set of host data or user data or application.

Certain memory devices, such as NAND-type memory devices, include one or more blocks, (e.g., multiple blocks), with each of those blocks including multiple memory cells. For instance, a memory device can include multiple pages (stored across one or more WLs), with each page including a subset of memory cells of the memory device. A threshold voltage (VT) of a memory cell (of a block) can be the voltage at which the floating gate (e.g., NAND transistor), implementing the memory cell, turns on and conducts (e.g., to a bit line coupled to the memory cell). Generally, writing data to such memory devices involves programming (by way of a program operation) the memory devices at the page level of a block, and erasing data from such memory devices involves erasing the memory devices at the block level (e.g., page level erasure of data is not possible).

In a three-dimensional (3D) NAND array, read disturb (RD) usually occurs during the complex interplay of different voltage levels applied during read operations. When reading data from a target WL, the memory controller applies a read voltage (Vread) to that specific WL while simultaneously applying higher pass voltages to all unselected WLs to ensure proper current sensing. The neighboring WLs immediately adjacent to the target WL receive an intermediate pass voltage (Vpass1), while all other unselected WLs receive an even higher pass voltage (Vpass) to ensure these cells remain turned on during the read operation.

This voltage configuration creates two distinct types of RD effects in the memory array. During sequential reading across WLs in a block, known as equal page RD, each WL experiences uniform bias stress from the high pass voltage. This stress can inadvertently program unselected cells, with erased cells being particularly vulnerable due to their higher potential difference. When hosts repeatedly read from specific WLs, known as single page read disturb, the lateral electric field between the target WL and its neighbor WLs generates hot electrons, with this effect being most pronounced when reading lower pages due to the voltage differential between the read level and neighboring pass voltages.

To manage these RD effects, conventional systems implement firmware algorithms that monitor RCs at the VB level. When a VB reaches its RC threshold, the memory controller initiates a RD scan on WLs in a list of WLs. The list of WLs includes a predefined list of mandatory WLs, the neighbor WLs of the most recently read WL, and/or the most recently read WL itself . If this RD scan detects elevated error rates (e.g., if the raw bit error rate (RBER) transgresses an RBER threshold), the memory controller refreshes the VB by relocating data from the VB to a new VB.

However, this conventional approach suffers from inefficiencies in its implementation. The challenge lies in determining the optimal size of the WL list that is scanned in the RD scan. A smaller WL list improves scan performance but risks missing vulnerable WLs across different blocks and dies. Conversely, a larger WL list provides better reliability coverage but can degrade read scan performance by increasing RD scan latency. Current solutions attempt to address these issues by dramatically expanding the mandatory WL list, resulting in a large increase in RD scan latency while still failing to effectively identify the most stressed WLs. The conventional approach particularly struggles with corner cases where heavily-read WLs outside the mandatory WL list become more vulnerable than those included in the WL list. For instance, in ping-pong test scenarios, where specific areas experience intense read activity, the neighbor WLs adjacent to these heavily-read areas may develop reliability issues after multiple iterations of bypassed RD scans. This occurs because the system's block-level read count tracking fails to capture the localized stress patterns that develop on specific WLs and their neighbors.

The present disclosure addresses these inefficiencies by implementing a dynamic WL tracking and management system that intelligently identifies and monitors stressed WLs. Rather than relying on a fixed, expanded mandatory WL list, the memory controller tracks read stress counts for WLs in a memory portion (e.g., a memory block or VB), monitoring both direct read operations on target WLs being read and stress effects on neighboring WLs. When a read count of the memory portion reaches a threshold associated with performing RDH operations, the memory controller selectively adds only those WLs having read stress counts that satisfy one or more criteria to the scan list (e.g., a list of WLs). This maintains an optimal balance between reliability and performance. This dynamic approach allows the memory controller to accurately identify the weakest WLs without compromising scan performance, as WLs are added to and removed from the scan list based on actual usage patterns. The system can be further optimized by tracking stress at a WLG level and implementing stress thresholds to minimize memory overhead while maintaining effective coverage. In this way, the disclosed techniques effectively address corner cases like ping-pong test scenarios by ensuring heavily stressed WLs are captured during RD scans, while avoiding the performance penalties associated with scanning an unnecessarily large fixed list of WLs.

In some examples, the techniques described herein relate to a system for managing read disturb effects in memory devices implements dynamic tracking and handling of stressed WLs. In some examples, the disclosed memory controller tracks read stress counts for WLs in a portion of the memory device, such as a VB or memory block, where the read stress counts indicate stress operations experienced during read operations. When a RC threshold is reached for that portion, the memory controller selectively adds WLs to a list containing predefined mandatory WLs based on their read stress counts, and performs RDH operations on the WLs in that list.

In some cases, the RDH operations include a RD scan to determine whether RBER for the WLs in the list exceed an RBER threshold. When such thresholds are transgressed, the memory controller refreshes the data in that portion of the memory device. After completing the RDH operations, the memory controller removes the selectively added WLs from the list, maintaining efficiency in subsequent operations.

In some examples, the memory controller maintains a table associating WLs or WLGs with their respective read stress counts. In some implementations, when receiving a request to read a target WL, the memory controller increments both the stress count for that target WL and the stress counts for its neighboring WLs immediately above and below. Alternatively, when operating at a WLG level, the memory controller increments a stress count associated with the entire WLG containing the target WL, representing accumulated read stress for multiple WLs within that WLG.

In some cases, different portions of the memory device may have different sized WL lists that are scanned as part of the RDH operations based on usage patterns. For instance, a first portion may have a different number of WLs in its list compared to a second portion, depending on how many WLs in each portion have read stress counts satisfying a read stress criteria (e.g., transgressing a stress threshold). The memory controller can identify WLs for inclusion in the list either by selecting those with the highest read stress counts or by identifying WLs whose stress counts exceed a defined threshold.

The predefined mandatory WLs in the list can include WLs that have been identified as particularly susceptible to read disturb effects. This approach can be particularly relevant for 3D NAND devices, where RD effects can impact memory reliability.

Though various examples are described herein as being implemented with respect to a memory sub-system (e.g., a controller of the memory sub-system), some or all of the portions of an example can be implemented with respect to a host system, such as a software application or an operating system of the host system.

FIG. 1 illustrates an example computing system 100 that includes a memory sub-system 110, in accordance with some examples. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, a secure digital (SD) card, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some examples, the host system 120 is coupled to different types of memory sub-systems 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

The host system 120 can include a processor chipset and a software stack executed by the processor chipset. The processor chipset can include one or more cores, one or more caches, a memory controller (e.g., NVDIMM controller), and a storage protocol controller (e.g., a peripheral component interconnect express (PCIe) controller, serial advanced technology attachment (SATA) controller). The host system 120 uses the memory sub-system 110, for example, to write data to the memory sub-system 110 and read data from the memory sub-system 110.

The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL) interface, a universal serial bus (USB) interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory devices 130, 140 when the memory sub-system 110 is coupled with the host system 120 by the PCIe or CXL interface. The physical host interface can provide an interface for passing control, address, data, and other signals between the memory sub-system 110 and the host system 120.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a NAND type flash memory and write-in-place memory, such as a 3D cross-point memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional (2D) NAND and 3D NAND.

Each of the memory devices 130, 140 can include one or more arrays of memory cells. One type of memory cell, for example, single level cells (SLCs), can store one bit per cell. Other types of memory cells, such as multi-level cells (MLCs), tri-level cells (TLCs), quad-level cells (QLCs), and penta-level cells (PLCs), can store multiple bits per cell. In some examples, each of the memory devices 130, 140 can include one or more arrays of memory cells such as SLCs, MLCs, TLCs, QLCs, or any combination of such. In some examples, a particular memory device can include an SLC portion, and an MLC portion, a TLC portion, or a QLC portion of memory cells. The memory cells of the memory devices 130, 140 can be grouped as pages that can refer to a logical unit of the memory device used to store data. With some types of memory (e.g., NAND), pages can be grouped to form blocks or BSs. As used herein, a block including SLCs can be referred to as a SLC block, a block including MLCs can be referred to as a MLC block, a block including TLCs can be referred to as a TLC block, and a block including QLCs can be referred to as a QLC block.

Although non-volatile memory components such as NAND type flash memory (e.g., 2D NAND, 3D NAND) and 3D cross-point array of non-volatile memory cells are described, the memory device 130 can be based on any other type of non-volatile memory, such as read-only memory (ROM), phase change memory (PCM), self-selecting memory, other chalcogenide-based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide-based RRAM (OxRAM), negative-or (NOR) flash memory, and electrically erasable programmable read-only memory (EEPROM).

A memory sub-system controller 115 (or controller 115 for simplicity) can communicate with the memory devices 130, 140 to perform operations such as reading data, writing data, or erasing data (e.g., performing GC operations) at the memory devices 130, 140 and other such operations. The memory sub-system controller 115 can include hardware such as one or more integrated circuits and/or discrete components, a buffer memory, or a combination thereof. The hardware can include digital circuitry with dedicated (e.g., hard-coded) logic to perform the operations described herein. The memory sub-system controller 115 can be a microcontroller, special purpose logic circuitry (e.g., a field programmable gate array (FPGA), an application specific integrated circuit (ASIC), and so forth), or other suitable processor.

The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some examples, the local memory 119 can include memory registers storing memory pointers, fetched data, and so forth. The local memory 119 can also include ROM for storing micro-code. While the example memory sub-system 110 in FIG. 1 has been illustrated as including the memory sub-system controller 115, in another example, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device 130 and/or the memory device 140. The memory sub-system controller 115 can be responsible for other operations such as wear leveling operations, GC operations, error detection and ECC operations, encryption operations, caching operations, and address translations between a logical address (e.g., LBA, namespace) and a physical memory address (e.g., physical block address in a physical address space of the memory device 130 or memory device 140) that are associated with the memory devices 130, 140. The memory sub-system controller 115 can further include host interface circuitry to communicate with the host system 120 via the physical host interface. The host interface circuitry can convert the commands received from the host system 120 into command instructions to access the memory device 130 and/or the memory device 140 as well as convert responses associated with the memory device 130 and/or the memory device 140 into information for the host system 120.

The memory sub-system 110 can also include additional circuitry or components that are not illustrated. In some examples, the memory sub-system 110 can include a cache or buffer (e.g., DRAM) and address circuitry (e.g., a row decoder and a column decoder) that can receive an address from the memory sub-system controller 115 and decode the address to access the memory devices 130, 140.

In some examples, the memory device 130 includes local media controllers 135 that operate in conjunction with memory sub-system controller 115 to execute operations on one or more memory cells of the memory device 130. An external controller (e.g., memory sub-system controller 115) can externally manage the memory device 130 (e.g., perform media management operations on the memory device 130). In some examples, a memory device 130 is a managed memory device, which is a raw memory device combined with a local controller (e.g., local media controller 135) for media management within the same memory device package. An example of a managed memory device is a managed NAND (mNAND) device. Any operation discussed as being performed by the memory sub-system controller 115 can be similarly performed by the local media controllers 135 and vice versa.

The memory sub-system controller 115 includes an RDH component 113 that enables or facilitates the memory sub-system controller 115 to implement a dynamic WL tracking and management system for RD handling. Upon receiving a request to read data from a specific WL in a block (e.g., a VB) that triggers a RDH operation, the RDH component 113 tracks read stress counts for WLs in the block, monitoring both direct read operations on target WLs being read and stress effects on neighboring WLs. When a read count threshold for the block is reached, the RDH component 113 identifies WLs associated with read stress counts that satisfy one or more criteria. The RDH component 113 can then dynamically add the identified WLs to a WL list that includes predefined mandatory WLs to be scanned in the RDH operations. Rather than scanning all WLs or maintaining a fixed scan list, the RDH component 113 selectively adds only those WLs with stress counts satisfying one or more criteria (e.g., having stress counts that exceed a defined threshold or having stress counts that is greater than stress counts of other WLs by some threshold amount), optimizing the balance between reliability and performance. The RDH component 113 then performs the RDH operation on the WL list (including the dynamically added WLs), removing the dynamically added WLs after performing the RDH operation. This approach enhances read disturb detection precision while maintaining efficient operation by avoiding unnecessary scanning of all WLs. This can significantly improve overall system performance and the efficiency of the memory sub-system.

The RDH component 113 enables the memory sub-system controller 115 to implement dynamic tracking and management of read disturb effects in memory devices 130. The RDH component 113 can maintain read stress counts for WLs in portions of the memory device, such as virtual blocks (VBs) or memory blocks, tracking both direct read operations on target WLs and stress effects experienced by neighboring WLs. When receiving a read request for a target WL, the RDH component 113 updates a tracking table that associates WLs with their respective stress counts. For individual WL tracking, the RDH component 113 increments both the stress count for the target WL being read and the stress counts for its immediately adjacent neighboring WLs (above and below). Alternatively, when implementing WL group-level tracking, the RDH component 113 increments an accumulated stress count for the entire WL group containing the target WL, representing collective stress for multiple WLs within that group.

The RDH component 113 monitors when a RC threshold is reached for a portion of the memory device 130. Namely, the RDH component 113 can increment a RC for the VB or portion each time the portion is read. The RDH component 113 can compare that current RC value of the VB or portion to the RC threshold. In response to determining that the RC threshold is exceeded or reached, the RDH component 113 initiates RDH operations on the portion, such as by performing RD scans on the portion. Upon reaching this threshold, as part of performing the RD scan operation, the RDH component 113 identifies WLs experiencing high stress levels using multiple possible criteria. For example, the RDH component 113 can select WLs with the highest comparative stress counts in the VB and/or identifying WLs whose stress counts exceed a stress count threshold. The identified WLs are then dynamically added to a scan WL list that includes predefined mandatory WLs known to be susceptible to read disturb effects and neighbor WLs of the last read WL.

The RDH component 113 can perform RDH operations on the WLs in this list, including RD scans to check for elevated RBERs. If RBER exceeds a defined RBER threshold during these scans, the RDH component 113 initiates a refresh operation to relocate data from the affected portion to a new VB. After completing the RDH operations, the RDH component 113 removes the dynamically added WLs from the list while maintaining the predefined mandatory WLs. The RDH component 113 can reset the stress count values for the WLs in the portion once the RDH operations are completed.

The RDH component 113 can implement different sized WL lists across different portions of the memory device 130 based on usage patterns. For example, portions experiencing more intensive read operations may have larger WL lists due to more WLs exceeding stress thresholds. To optimize memory usage, the RDH component 113 can also implement stress count thresholds to limit tracking to only those WLs experiencing stress levels higher than the stress count thresholds.

For 3D NAND devices, the RDH component 113 can address RD effects caused by voltage differentials during read operations. When reading a target WL, neighboring WLs receive an intermediate pass voltage (Vpass1) while other unselected WLs receive a higher pass voltage (Vpass), creating potential stress patterns that the RDH component 113 can monitor and manage. This dynamic approach allows the RDH component 113 to maintain optimal balance between reliability and performance by avoiding unnecessary scanning of all WLs while ensuring adequate coverage of stressed WLs. The ability of the RDH component 113 to adjust WL list sizes based on actual usage patterns and stress levels helps prevent reliability issues in corner cases like ping-pong test scenarios where specific areas experience intense read activity.

Any discussion with respect to the memory device 130 can similarly be applied to the memory device 140.

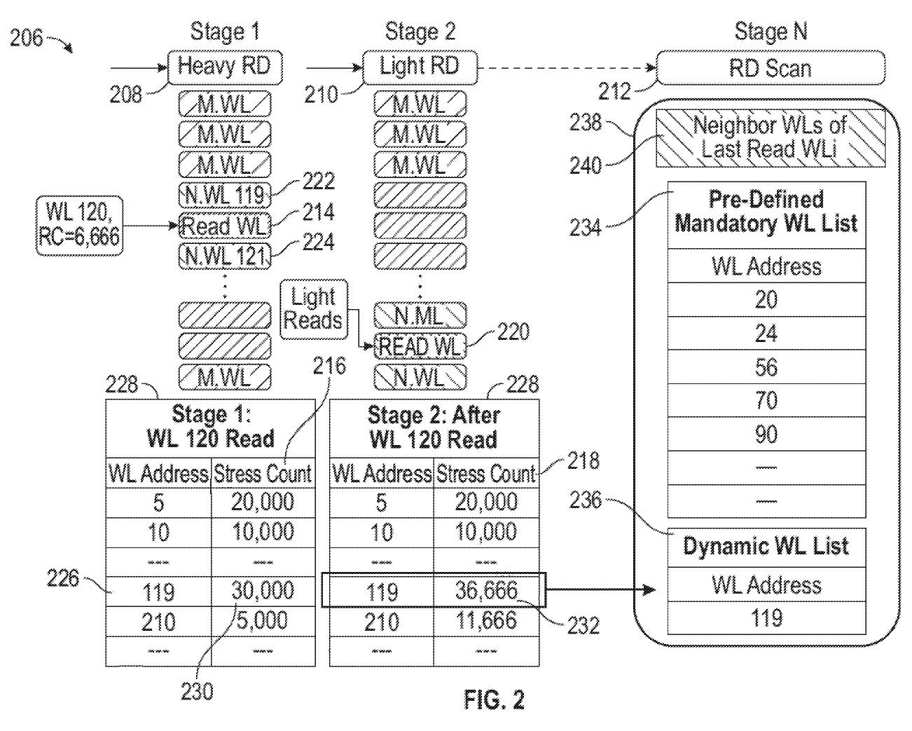

FIG. 2 illustrates a diagram 206 of stages for selectively adding WLs for RDH operations, in accordance with some examples. Specifically, the diagram 206 shows how the RDH component 113 performs RD handling operations across multiple stages. The diagram 206 includes a first stage 208 and a second stage 210 that demonstrate how the RDH component 113 tracks and manages read stress counts during read operations. The first stage 208 represents read operations that take place during a first period of time and the second stage 210 represents subsequent read operations that take place in a second period of time (which can be the same or different from the first period of time).

In some examples, in the first stage 208, the RDH component 113 receives from the host system 120 one or more requests to read a first WL 214 (e.g., WL120) from an individual VB. The first stage 208 can take place after previous stages performed other read operations on the individual VB. The RDH component 113 processes the read requests as read operations on the first WL 214. As a result, the first WL 214 experiences heavy RD stress (e.g., by receiving 6,666 read operations). During this first stage 208, the RDH component 113 maintains first stage stress counts 216 in a stress counts table 228.

The stress counts table 228 tracks read stress counts for various WLs, excluding those in the predefined mandatory WL list 234. The stress counts table 228 shows different WLs with their associated stress counts, including a first neighbor WL entry 226 for first neighbor WL 222 (e.g., WL 119) with a first stress count 230 (e.g., a stress count of 30,000). The stress counts table 228 includes a second neighbor WL entry for second neighbor WL 224 (e.g., WL 121) (not shown) with a second stress count.

In the first stage 208, when the RDH component 113 receives requests to the first WL 214, the RDH component 113 processes these read operations and updates the stress counts table 228 accordingly. For example, for each read operation on first WL 214 (e.g., WL120), the RDH component 113 not only increments the stress count for WL120 itself but also increments the stress counts for its neighboring WLs (e.g., WL119 (first neighbor WL 222) and WL121 (second neighbor WL 224)). The stress counts table 228 shows that before processing the 6,666 read operations on WL120, WL119 had accumulated a stress count of 30,000 (first stress count 230). After processing these read operations in the first stage 208, the RDH component 113 adds the 6,666 stress operations to WL119's count, bringing its total to the second stress count 232 (e.g., 36,666) in the second stage stress counts 218.

Similarly, for WL121 (second neighbor WL 224), the stress count in the stress counts table 228 is incremented from 5,000 to 11,666 after processing the 6,666 read operations on WL120. This demonstrates how the RDH component 113 tracks both direct read stress on the target WL (e.g., the first WL 214) and the accumulated stress effects on neighboring WLs (e.g., first neighbor WL 222 and second neighbor WL 224) during read operations. The RDH component 113 maintains these stress counts separately from the predefined mandatory WLs in the mandatory WL list 234, focusing on tracking stress patterns for WLs that may need to be dynamically added to the scan list based on their accumulated stress levels. This incremental tracking ensures that WLs experiencing stress, either directly or through neighboring read operations, are properly identified for inclusion in subsequent read disturb scans.

Moving to second stage 210, after the read operation on first WL 214, the RDH component 113 updates the stress counts in the table to reflect second stage stress counts 218. The component particularly focuses on the first neighbor WL 222 (WL 119) and second neighbor WL 224 (WL 121), which are adjacent to the heavily-read WL120. In the second stage 210, the RDH component 113 can receive a request to read the second WL 220. In response to this request to read the second WL 220, the RDH component 113 similar updates the corresponding stress counts in the stress counts table 228. The RDH component 113 can update the RC for the VB in response to the request to read the second WL 220. The RDH component 113 can determine that the current RC of the VB transgresses an RC threshold. In such cases, the RDH component 113 initiates RDH operations (e.g., the RD scan 212) on the VB.

As part of initiating the RDH operations, the RDH component 113 generates a list of WLs for RDH operations 238 that are scanned in the RDH operation (e.g., the list of WLs that are scanned as part of the RD scan). The list of WLs for RDH operations 238 includes neighbor WLs of last read WL 240 (these can include the neighboring WLs of the second WL 220). The list of WLs for RDH operations 238 also includes mandatory WL list 234. The RDH component 113 maintains a predefined mandatory WL list 234 that includes WLs identified as particularly susceptible to RD effects. This list represents the baseline WLs that will always be included in read disturb scans. When the read count threshold is reached, the RDH component 113 identifies WLs with high stress counts to be added as selectively added WLs 236. These WLs, combined with the mandatory WL list 234, form the complete list of WLs for RDH operations 238.

The list of WLs for RDH operations 238 can also include selectively added WLs 236 (e.g., a dynamically added list of WLs). The WLs selectively added to the selectively added WLs 236 can be based on the stress counts stored in the stress counts table 228.

When determining whether to add WLs to the selectively added WLs 236, the RDH component 113 analyzes the stress counts in stress counts table 228 using one or more criteria. For example, the RDH component 113 can identify WLs that have either accumulated the highest comparative stress counts or exceeded defined stress thresholds. Namely, when WL 119's stress count increases to 36,666 in the second stage stress counts 218, the RDH component 113 compares this value against other WLs in the stress counts table 228 to determine if WL 119 should be added to selectively added WLs 236. The RDH component 113 can identify this WL 119 as having significantly higher stress than others by determining whether WL 119's stress count exceeds the stress counts of other WLs by more than a threshold amount. For instance, WL 119's stress count of 36,666 is greater than WL 121's stress count of 11,666 by more than 25,000 reads, which could represent a threshold difference that triggers WL119's inclusion in the selectively added WLs 236. This comparative threshold approach ensures that only WLs experiencing significantly higher stress relative to their peers are added to the scan list, rather than simply identifying WLs with high absolute stress counts.

The RDH component 113 may also apply specific stress count thresholds to determine inclusion. For instance, if a WL's stress count exceeds a predetermined threshold (such as 30,000 reads), the RDH component 113 automatically adds it to selectively added WLs 236. The RDH component 113 can implement different thresholds or criteria based on usage patterns across different portions of the memory device. For heavily-used portions, the threshold might be higher to prevent excessive WL additions, while less-used portions might have lower thresholds to ensure adequate monitoring.

When adding WLs to selectively added WLs 236, the RDH component 113 considers both direct read stress and neighboring effects. For example, both WL 119 and WL 121 may be added due to their accumulated stress from being neighbors to the heavily-read WL120. The RDH component 113 maintains the dynamic nature of selectively added WLs 236 by continuously evaluating stress counts against the criteria as new read operations occur. This ensures the list remains current with actual usage patterns.

After completing the RDH operation (e.g., RD scan 212), the RDH component 113 systematically removes all WLs from selectively added WLs 236. This removal process maintains system efficiency by ensuring only currently stressed WLs are included in future scans. The removal process does not affect the mandatory WL list 234 or the neighbor WLs of last read WL 240, as these remain constant parts of the list of WLs for RDH operations 238. This preserves the baseline protection while allowing for dynamic additions based on actual stress patterns.

The RDH component 113 may also implement different removal strategies based on the results of the RDH operation. For instance, if high error rates are detected during the scan, the RDH component 113 might retain certain WLs in selectively added WLs 236 for the next scan before removing them. This dynamic addition and removal process allows the RDH component 113 to maintain optimal balance between comprehensive coverage and efficient operation, ensuring stressed WLs are properly monitored while avoiding unnecessary scanning of unstressed WLs.

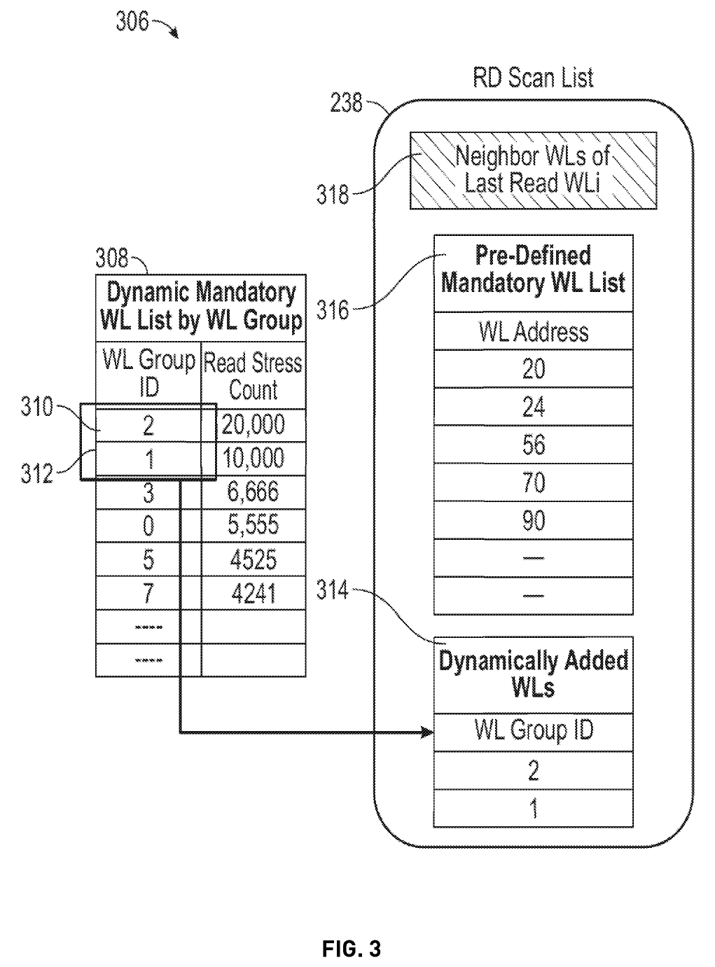

FIG. 3 illustrates a diagram 306 of a table for tracking read stress counts for WL groups, in accordance with some examples. The diagram 306 shows how the RDH component 113 implements RD handling at a WLG level to optimize memory usage while maintaining effective coverage. The diagram 306 shows a list of WLs for RDH operations 238 (e.g., an RD scan list) that combines multiple elements to ensure comprehensive RD protection.

The list of WLs for RDH operations 238 can include neighbor WLs of last read WL 318, which are tracked to monitor stress effects on WLs adjacent to recently accessed areas. These neighbor WLs are automatically included in the scan list regardless of their individual stress counts to ensure proper coverage of potentially affected areas.

The list of WLs for RDH operations 238 also includes a set of mandatory WLs 316 containing WLs that have been identified as particularly susceptible to RD effects. This mandatory WLs 316 list includes specific WL addresses (20, 24, 56, 70, 90) that are always scanned during RDH operations. The RDH component 113 implements a dynamic WL list 308 by WLG, which tracks stress counts at a WL group level rather than individual WL level. This approach helps reduce memory overhead while maintaining effective monitoring of stressed areas.

The WLG tracking table including dynamic WL list 308 shows different WL groups with their associated read stress counts. For example, WLG 2 has accumulated 20,000 read stress counts, while WLG 1 accumulated 10,000 read stress counts. This group-level tracking allows the RDH component 113 to identify heavily stressed sections of memory more efficiently.

For example, when the RDH component 113 receives a request to read a target WL, the RDH component 113 updates the dynamic WL list 308 by incrementing the read stress count for the entire WL group containing that target WL. For example, if a read request targets a WL within WLG 2, the RDH component 113 increments the accumulated read stress count for that entire group, which currently shows 20,000 reads in the tracking table. The RDH component 113 also increments the read stress counts for other WL groups that contain the neighboring WLs above and below the target WL.

This group-level tracking means that rather than maintaining individual stress counts for each WL, the RDH component 113 maintains a collective stress count that represents the accumulated read stress for all WLs within that group. For instance, if WL56 (which appears in the mandatory WL list) receives a read request, the RDH component 113 would increment the stress count for its entire WL group (group 1, showing 10,000 reads).

The WL groups typically contain 20-30 WLs each, allowing the RDH component 113 to efficiently track stress patterns across larger memory sections while reducing the memory overhead required for tracking. When any WL within a group is read, that single read operation contributes to the group's overall stress count, providing a comprehensive view of stress accumulation within that memory section.

For example, if a WL in group 3 (showing 6,666 reads) receives a read request, the RDH component 113 would increment that group's read count, potentially pushing it closer to thresholds that would trigger inclusion in the RD scan list. This group-based approach allows the system to identify heavily stressed memory sections without tracking individual WL stress counts, providing an efficient balance between granular monitoring and system resource usage.

The diagram 306 demonstrates how the RDH component 113 organizes WLs into groups, such as first WLG 310 and second WLG 312 to optimize tracking and management. Each WL group can contain approximately 20-30 WLs, allowing for efficient monitoring of stress patterns across larger memory sections. When an individual WLG has a read stress count that exceeds certain thresholds or meets a read stress criterion, the RDH component 113 can add WLs from that group to the scan list by adding the WLs to the selectively added WLGs 314 in the list of WLs for RDH operations 238. This group-based approach provides a balance between granular tracking and memory efficiency.

The overall structure shown in diagram 306 demonstrates how the RDH component 113 combines fixed mandatory elements with dynamic group-based tracking to create an efficient and comprehensive RD handling system. This approach allows for effective monitoring of stress patterns while optimizing system resources.

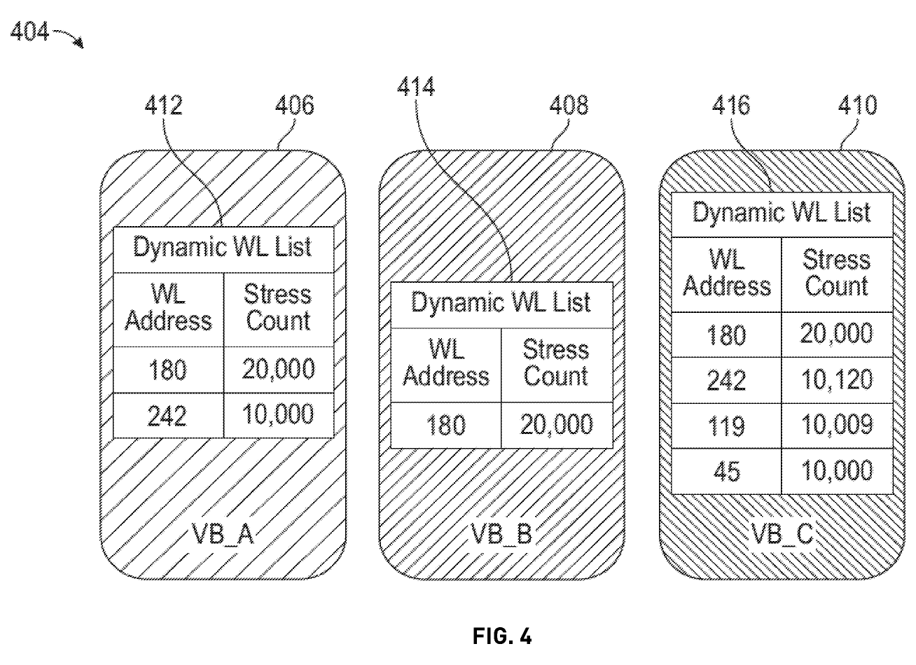

FIG. 4 illustrates a diagram 404 of different lists of WLs satisfying read stress count criteria for different VBs, in accordance with some examples. The diagram 404 shows how the RDH component 113 implements dynamic WL lists across different VBs of the memory device 130. The diagram 404 demonstrates three VBs including a first virtual block 406 (VB_A), a second virtual block 408 (VB_B), and a third virtual block 410 (VB_C), each maintaining their own dynamic WL lists, first dynamic WL list 412, second dynamic WL list 414, and third dynamic WL list 416.

The first dynamic WL list 412 associated with the first virtual block 406 shows two WLs with their corresponding stress counts. WL180 has accumulated 20,000 stress counts, while WL 242 has accumulated 10,000 stress counts, representing the most stressed WLs in that VB. The second dynamic WL list 414 for the second virtual block 408 contains four WLs, demonstrating how different VBs can have varying numbers of WLs in their lists based on actual usage patterns. This list includes WL180 (20,000 stress counts), WL 242 (10,120 stress counts), WL 119 (10,009 stress counts), and WL45 (10,000 stress counts). The third dynamic WL list 416 for third virtual block 410 shows yet another variation in list size and stress count distribution. This demonstrates how the RDH component 113 maintains separate tracking for each VB, allowing for customized read disturb handling based on specific usage patterns.

The varying sizes of the first dynamic WL list 412, second dynamic WL list 414, and third dynamic WL list 416 illustrate how the RDH component 113 adjusts list sizes (e.g., the size of the list of WLs for RDH operations 238) based on the number of WLs exceeding stress thresholds in each VB. For example, second virtual block 408 has more WLs in its list compared to first virtual block 406 because more WLs in second virtual block 408 have experienced significant stress.

The stress counts shown in the dynamic WL lists indicate different stress patterns across the VBs. Some WLs, like WL180, show consistently high stress counts across multiple VBs, while others appear only in specific VB lists. The RDH component 113 maintains these separate dynamic WL lists to ensure optimal coverage of stressed WLs while avoiding unnecessary scanning of unstressed areas. This VB-specific approach allows for more efficient read disturb handling compared to using a single fixed list size across all VBs.

Each dynamic WL list contains only those WLs whose stress counts exceed defined thresholds, ensuring focused monitoring of potentially vulnerable areas. The lists are updated dynamically as stress counts change, with WLs being added or removed based on their current stress levels. The presence of WL180 with 20,000 stress counts in multiple VB lists demonstrates how certain WLs may consistently experience heavy read stress across different VBs. This information helps the RDH component 113 identify patterns of stress distribution across the memory device.

The varying stress counts shown in the lists (ranging from 10,000 to 20,000) indicate different levels of read intensity across different VBs. This granular tracking allows the RDH component 113 to adjust its read disturb handling approach based on actual usage patterns. The structure of the dynamic WL lists enables efficient tracking and management of stressed WLs while maintaining separate lists for each VB. This approach allows the RDH component 113 to optimize both reliability coverage and system performance.

The consistent format of the dynamic WL lists across VBs (showing WL address and stress count) allows for easy comparison and management of stress patterns. This standardized tracking enables the RDH component 113 to make informed decisions about which WLs to include in read disturb scans.

Each VB's dynamic WL list is managed independently, allowing for targeted read disturb handling based on the specific stress patterns observed in that VB. This independent management ensures that read disturb protection is optimized for each VB's unique usage characteristics. The overall structure shown in diagram 404 illustrates how the RDH component 113 implements a flexible, efficient approach to tracking and managing stressed WLs across multiple VBs. This approach enables comprehensive read disturb protection while optimizing system resources through VB-specific list management.

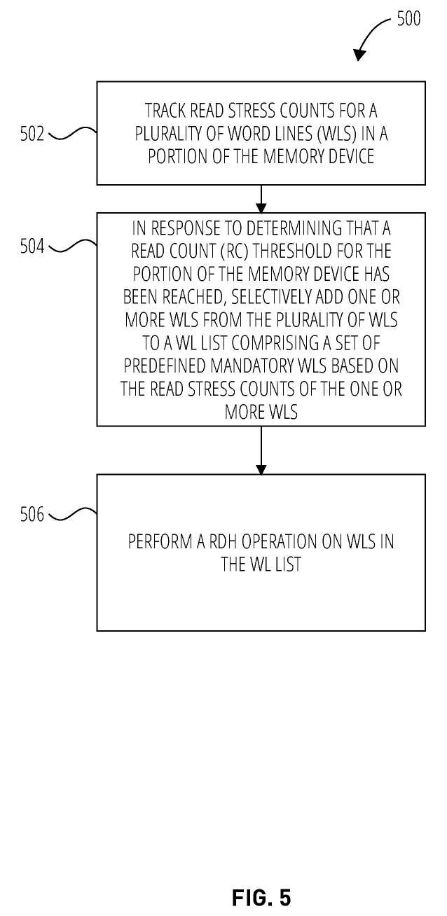

FIG. 5 is a flow diagram of an example diagram 500 (method or process) performed using the RDH component 113, in accordance with some examples. The method or process of diagram 500 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method or process of diagram 500 is performed by the memory sub-system controller 115 or subcomponents of the memory sub-system controller 115 of FIG. 1. In these examples, the method or process of diagram 500 can be performed, at least in part, by the RDH component 113. Although the processes are shown in a particular sequence or order, unless otherwise specified, the order of the processes can be modified. Thus, the illustrated examples should be understood only as examples; the illustrated processes can be performed in a different order, and some processes can be performed in parallel. Additionally, one or more processes can be omitted in various examples. Thus, not all processes are required in every example. Other process flows are possible.

Referring now to FIG. 5, the method or process of diagram 500 begins at operation 502, with the RDH component 113 of a memory sub-system 110 (e.g., memory device 140) tracking read stress counts for a plurality of WLs in a portion of the memory device. Then, at operation 504, the RDH component 113, in response to determining that a RC threshold for the portion of the memory device has been reached, selectively adds one or more WLs from the plurality of WLs to a WL list comprising a set of predefined mandatory WLs based on the read stress counts of the one or more WLs. The RDH component 113, at operation 506 performs a RDH operation on WLs in the WL list.

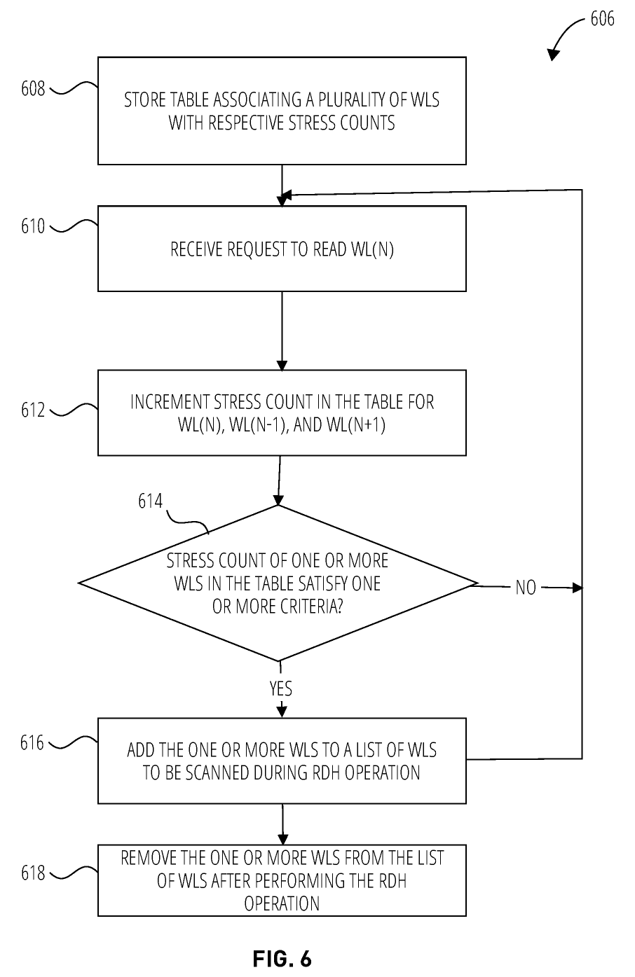

FIG. 6 is a flow diagram of an example diagram 606 (method or process) performed using the RDH component 113, in accordance with some examples. The method or process of diagram 500 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method or process of diagram 606 is performed by the memory sub-system controller 115 or subcomponents of the memory sub-system controller 115 of FIG. 1. In these examples, the method or process of diagram 606 can be performed, at least in part, by the RDH component 113. Although the processes are shown in a particular sequence or order, unless otherwise specified, the order of the processes can be modified. Thus, the illustrated examples should be understood only as examples; the illustrated processes can be performed in a different order, and some processes can be performed in parallel. Additionally, one or more processes can be omitted in various examples. Thus, not all processes are required in every example. Other process flows are possible.

Referring now to FIG. 6, the method or process of diagram 606 begins at operation 608, with the RDH component 113 storing a table associating a plurality of WLs with respective stress counts. At operation 610, the RDH component 113 receives a request to read WL(N). Then at operation 612, the RDH component 113 increments the stress count in the table for WL(N), WL(N-1), and WL(N+1). At operation 614, the RDH component 113 determines whether stress counts of one or more WLs in the table satisfy one or more criteria. If yes, at operation 616, the RDH component 113 adds the one or more WLs to a list of WLs to be scanned during RDH operation. At operation 618, the RDH component 113 removes the one or more WLs from the list of WLs after performing the RDH operation.

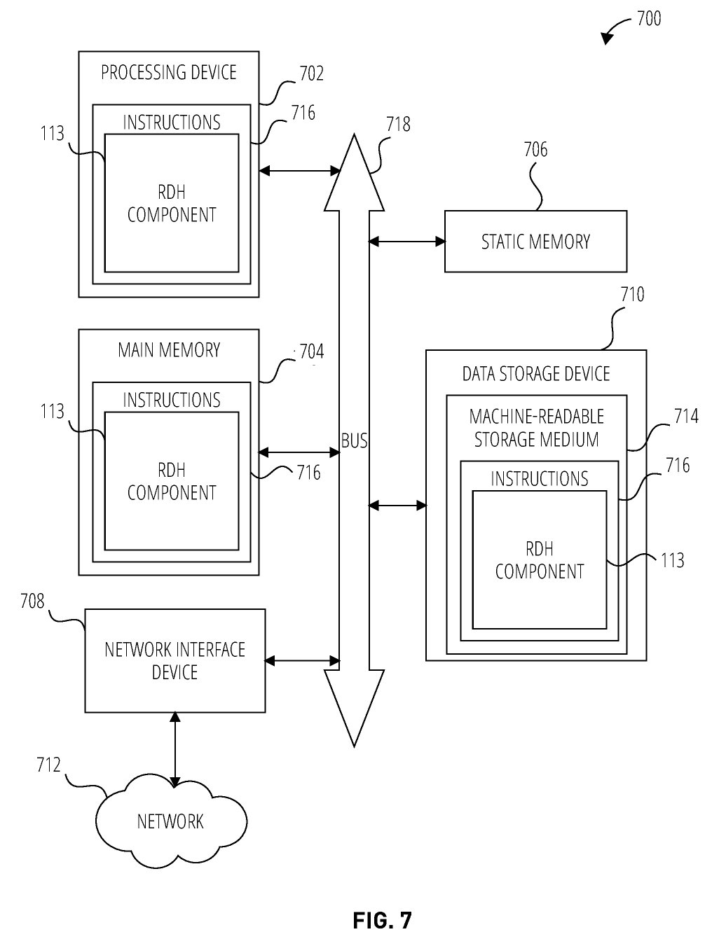

FIG. 7 illustrates an example machine in the form of a computer system 700 within which a set of instructions can be executed for causing the machine to perform any one or more of the methodologies discussed herein. In some examples, the computer system 700 can correspond to a host system (e.g., the host system 120 of FIG. 1) that includes, is coupled to, or utilizes a memory sub-system (e.g., the memory sub-system 110 of FIG. 1) or can be used to perform the operations described herein. In alternative examples, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 700 includes a processing device 702, a main memory 704 (e.g., ROM, flash memory, DRAM such as SDRAM or Rambus DRAM (RDRAM), etc.), a static memory 706 (e.g., flash memory, static random access memory (SRAM), etc.), and a data storage device 710, which communicate with each other via a bus 718.

The processing device 702 represents one or more general-purpose processing devices such as a microprocessor, a central processing unit, or the like. More particularly, the processing device 702 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 702 can also be one or more special-purpose processing devices such as an application-specific integrated circuit (ASIC), a field programmable gate array (FPGA), a digital signal processor (DSP), a network processor, or the like. The processing device 702 is configured to execute instructions 716 for performing the operations and steps discussed herein. The computer system 700 can further include a network interface device 708 to communicate over a network 712.

The data storage device 710 can include a machine-readable storage medium 714 (also known as a computer-readable medium) on which is stored one or more sets of instructions 716 or software embodying any one or more of the methodologies or functions described herein. The instructions 716 can also reside, completely or at least partially, within the main memory 704 and/or within the processing device 702 during execution thereof by the computer system 700, the main memory 704 and the processing device 702 also constituting machine-readable storage media. The machine-readable storage medium 714, data storage device 710, and/or main memory 704 can correspond to the memory sub-system 110 of FIG. 1.

In one example, the instructions 716 include instructions to implement functionality corresponding to providing block failure protection for a zone memory sub-system as described herein (e.g., the RDH component 113 of FIG. 1). While the machine-readable storage medium 714 is shown in an example to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Described implementations of the subject matter can include one or more features, alone or in combination as illustrated below by way of examples.

Example 1. A system comprising: a memory device; and a processing device, operatively coupled to the memory device, configured to perform operations comprising: tracking read stress counts for a plurality of WLs in a portion of the memory device; in response to determining that a read count (RC) threshold for the portion of the memory device has been reached, selectively adding one or more WLs from the plurality of WLs to a WL list comprising a set of predefined mandatory WLs based on the read stress counts of the one or more WLs; and performing a RDH operation on WLs in the WL list.

Example 2. The system of Example 1, wherein the portion comprises a memory block or virtual block (VB).

Example 3. The system of Example 2, wherein performing the RDH operation comprises performing an RD scan for determining whether raw bit error rates (RBER) for the WLs in the WL list exceed an RBER threshold.

Example 4. The system of Example 3, the operations comprising: refreshing data in the portion of the memory device in response to determining that the RBER transgresses the RBER threshold.

Example 5. The system of any one of Examples 1-4, wherein the read stress counts indicate stress operations experienced by WLs during read operations.

Example 6. The system of any one of Examples 1-5, the operations comprising: removing the selectively added one or more WLs from the WL list after completing the RDH operation.

Example 7. The system of any one of Examples 1-6, wherein the read stress counts exclude read stress counts for the predefined mandatory WLs.

Example 8. The system of any one of Examples 1-7, the operations comprise: adjusting a size of the WL list based on one or more usage patterns of the portion of the memory device.

Example 9. The system of Example 8, wherein the one or more usage patterns comprise read stress counts associated with the portion of the memory device.

Example 10. The system of Example 9, wherein the portion is a first portion, wherein the memory device comprises a second portion, the operations comprising: associating a first set of WLs of the first portion with a first set of read stress counts; associating a second set of WLs of the second portion with a second set of read stress counts; generating a first list of WLs to be scanned during the RDH operation performed with respect to the first portion by adding a first subset of the first set of WLs for which the read stress counts in the first set of read stress counts transgresses a read stress count threshold; and generating a second list of WLs to be scanned during the RDH operation performed with respect to the second portion by adding a second subset of the second set of WLs for which the read stress counts in the second set of read stress counts transgresses the read stress count threshold, the second list of WLs having a greater number of WLs than the first list of WLs.

Example 11. The system of any one of Examples 1-10, the operations comprising: storing a table that associates the plurality of WLs or WLGs with respective read stress counts.

Example 12. The system of Example 11, the operations comprising: receiving a request to read a target WL from the plurality of WLs of the portion of the memory device; and in response to receiving the request to read the target WL, incrementing a stress count int he table associated with the target WL being read and incrementing stress counts in the table for neighboring WLs adjacent to the target WL.

Example 13. The system of Example 12, wherein the neighboring WLs comprise WLs immediately above and below the target WL.

Example 14. The system of any one of Examples 11-13, the operations comprising: receiving a request to read a target WL from a WL group of the portion of the memory device; and in response to receiving the request to read the target WL, incrementing a stress count associated with the WL group containing the target WL, wherein the stress count represents accumulated read stress for multiple WLs within the WL group.

Example 15. The system of any one of Examples 1-14, the operations comprising: identifying the one or more WLs in the plurality of WLs having corresponding read stress counts that are greater than other WLs in the plurality of WLs; and adding the identified one or more WLs to the WL list.

Example 16. The system of any one of Examples 1-15, the operations comprising: identifying the one or more WLs in the plurality of WLs having corresponding read stress counts that transgress a read stress count threshold; and adding the identified one or more WLs to the WL list.

Example 17. The system of any one of Examples 1-16, wherein the predefined mandatory WLs comprise WLs identified as susceptible to read disturb (RD) effects.

Example 18. The system of any one of Examples 1-17, wherein the memory device comprises a 3D NAND device.

Example 19. At least one non-transitory machine-readable storage medium comprising instructions that, when executed by a processing device, cause the processing device to perform operations comprising: tracking read stress counts for a plurality of WLs in a portion of a memory device; in response to determining that a RC threshold for the portion of the memory device has been reached, selectively adding one or more WLs from the plurality of WLs to a WL list comprising a set of predefined mandatory WLs based on the read stress counts of the one or more WLs; and performing a RDH operation on WLs in the WL list.

Example 20. A method comprising: tracking read stress counts for a plurality of WLs in a portion of a memory device; in response to determining that a RC threshold for the portion of the memory device has been reached, selectively adding one or more WLs from the plurality of WLs to a WL list comprising a set of predefined mandatory WLs based on the read stress counts of the one or more WLs; and performing a RDH operation on WLs in the WL list.

The term “coupled with” generally refers to a connection between components, which can be an indirect communicative connection or direct communicative connection (e.g., without intervening components), whether wired or wireless, including connections such as electrical, optical, magnetic, and the like.

“System data” hereinafter refers to data that is created and/or maintained by the memory sub-system for performing operations in response to host requests and for media management.

“User data” hereinafter generally refers to host data and garbage collection data.

“Read disturb” refers to a phenomenon where repeated read operations on a specific WL in a NAND flash memory block cause unintended changes in the threshold voltages of adjacent cells on unselected WLs within the same block. This effect can potentially lead to data corruption in neighboring cells if left unmanaged, necessitating periodic data refresh or block relocation (folding) operations to maintain data integrity in NAND-based storage devices.

“Folding” refers to an operation where data from multiple partially filled pages or blocks is combined and rewritten into a single page or block. This process helps to optimize storage space utilization, reduce write amplification, and improve overall performance of the NAND storage device by consolidating fragmented data and freeing up space for new writes. Folding and “relocation” operations are used interchangeably and mean the same thing.

“High-risk WLs” or “mandatory WLs” refer to WLs within a NAND flash memory block that are more susceptible to data corruption or errors due to various factors, such as frequent read operations, physical location within the block, and/or proximity to heavily accessed areas. These WLs can require more frequent monitoring, error checking, and potential data refresh or relocation operations to maintain data integrity and overall reliability of the NAND storage device. These WLs can be predetermined and stored as part of configuration data of the memory sub-system.

“Virtual blocks (VB)” represent a logical grouping of memory cells in the memory device that is read at the same time. The VB can include multiple memory blocks that span across multiple memory dies.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks, ROMs, RAMs, EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium (such as a non-transitory machine-readable medium) having stored thereon instructions, which can be used to program a computer system (or other electronic devices) to perform a process according to the present disclosure. A machine-readable medium includes any mechanism for storing information in a form readable by a machine (e.g., a computer). In some examples, a machine-readable (e.g., computer-readable) medium includes a machine (e.g., a computer) readable storage medium such as a ROM, RAM, magnetic disk storage media, optical storage media, flash memory components, and so forth. A machine-readable storage medium can be non-transitory (in other words, not having any transitory signals) in that it does not embody a propagating signal. However, labeling a machine-readable storage medium “non-transitory” should not be construed to mean that the machine-readable storage medium is incapable of movement; the machine-readable storage medium should be considered as being transportable from one physical location to another.

In the foregoing specification, examples of the disclosure have been described with reference to specific examples thereof. It will be evident that various modifications can be made thereto without departing from the broader scope of examples of the disclosure as set forth in the following claims. The specification and drawings are, accordingly, to be regarded in an illustrative sense rather than a restrictive sense.

What is claimed is:

1. A system comprising:
a memory device; and
a processing device, operatively coupled to the memory device, configured to perform operations comprising:
tracking read stress counts for a plurality of word lines (WLs) in a portion of the memory device;
in response to determining that a read count (RC) threshold for the portion of the memory device has been reached, selectively adding one or more WLs from the plurality of WLs to a WL list comprising a set of predefined mandatory WLs based on the read stress counts of the one or more WLs; and
performing a read disturb handling (RDH) operation on WLs in the WL list.

2. The system of claim 1, wherein the portion comprises a memory block or virtual block (VB).

3. The system of claim 2, wherein performing the RDH operation comprises performing an RD scan for determining whether raw bit error rates (RBER) for the WLs in the WL list exceed an RBER threshold.

4. The system of claim 3, the operations comprising:
refreshing data in the portion of the memory device in response to determining that the RBER transgresses the RBER threshold.

5. The system of claim 1, wherein the read stress counts indicate stress operations experienced by WLs during read operations.

6. The system of claim 1, the operations comprising:
removing the selectively added one or more WLs from the WL list after completing the RDH operation.

7. The system of claim 1, wherein the read stress counts exclude read stress counts for the predefined mandatory WLs.

8. The system of claim 1, the operations comprise:
adjusting a size of the WL list based on one or more usage patterns of the portion of the memory device.

9. The system of claim 8, wherein the one or more usage patterns comprise read stress counts associated with the portion of the memory device.

10. The system of claim 9, wherein the portion is a first portion, wherein the memory device comprises a second portion, the operations comprising:
associating a first set of WLs of the first portion with a first set of read stress counts;
associating a second set of WLs of the second portion with a second set of read stress counts;
generating a first list of WLs to be scanned during the RDH operation performed with respect to the first portion by adding a first subset of the first set of WLs for which the read stress counts in the first set of read stress counts transgresses a read stress count threshold; and
generating a second list of WLs to be scanned during the RDH operation performed with respect to the second portion by adding a second subset of the second set of WLs for which the read stress counts in the second set of read stress counts transgresses the read stress count threshold, the second list of WLs having a greater number of WLs than the first list of WLs.

11. The system of claim 1, the operations comprising:
storing a table that associates the plurality of WLs or WL groups (WLGs) with respective read stress counts.

12. The system of claim 11, the operations comprising:
receiving a request to read a target WL from the plurality of WLs of the portion of the memory device; and
in response to receiving the request to read the target WL, incrementing a stress count int he table associated with the target WL being read and incrementing stress counts in the table for neighboring WLs adjacent to the target WL.

13. The system of claim 12, wherein the neighboring WLs comprise WLs immediately above and below the target WL.

14. The system of claim 11, the operations comprising:
receiving a request to read a target WL from a WL group of the portion of the memory device; and
in response to receiving the request to read the target WL, incrementing a stress count associated with the WL group containing the target WL, wherein the stress count represents accumulated read stress for multiple WLs within the WL group.

15. The system of claim 1, the operations comprising:
identifying the one or more WLs in the plurality of WLs having corresponding read stress counts that are greater than other WLs in the plurality of WLs; and
adding the identified one or more WLs to the WL list.

16. The system of claim 1, the operations comprising:
identifying the one or more WLs in the plurality of WLs having corresponding read stress counts that transgress a read stress count threshold; and
adding the identified one or more WLs to the WL list.

17. The system of claim 1, wherein the predefined mandatory WLs comprise WLs identified as susceptible to read disturb (RD) effects.

18. The system of claim 1, wherein the memory device comprises a three-dimensional (3D) NAND device.

19. At least one non-transitory machine-readable storage medium comprising instructions that, when executed by a processing device, cause the processing device to perform operations comprising:
tracking read stress counts for a plurality of word lines (WLs) in a portion of a memory device;
in response to determining that a read count (RC) threshold for the portion of the memory device has been reached, selectively adding one or more WLs from the plurality of WLs to a WL list comprising a set of predefined mandatory WLs based on the read stress counts of the one or more WLs; and
performing a read disturb handling (RDH) operation on WLs in the WL list.

20. A method comprising:
tracking read stress counts for a plurality of word lines (WLs) in a portion of a memory device;
in response to determining that a read count (RC) threshold for the portion of the memory device has been reached, selectively adding one or more WLs from the plurality of WLs to a WL list comprising a set of predefined mandatory WLs based on the read stress counts of the one or more WLs; and
performing a read disturb handling (RDH) operation on WLs in the WL list.
